(19) United States
(12) Patent Application Publication
(10) Pub. No.: US 2014/0318621 A1
(43) Pub. Date: Oct. 30, 2014

(54) SOLAR CELL MODULE AND PHOTOVOLTAIC POWER GENERATION DEVICE

(71) Applicant: Sharp Kabushiki Kaisha, Osaka-shi, Osaka (JP)

(72) Inventors: Tokiyoshi UMEDA, Osaka-shi (JP); Hideki UCHIDA, Osaka-shi (JP); Hideomi YUI, Osaka-shi (JP)

(21) Appl. No.: 14/345,475

(22) PCT Filed: Sep. 19, 2012
(86) PCT No.: PCT/JP2012/073939

§ 371 Date: Mar. 18, 2014

(30) Foreign Application Priority Data
Sep. 22, 2011 (JP) 2011-208030

(51) Int. Cl. H01L 31/055

(52) U.S. Cl. CPC H01L 31/055
USPC 136/259

(57) ABSTRACT

A solar cell module includes a light guide and a solar cell element. The light guide has a light incident surface and a light exit surface having an area smaller than the light incident surface and contains a plurality of optical functional materials. In the light guide, part of external light incident on the light incident surface is absorbed by the plurality of optical functional materials, Foerster energy transfer occurs among the plurality of optical functional materials, and light emitted by the optical functional material having the longest peak wavelength of the emission spectrum among the plurality of optical functional materials is collected to and exits from the light exit surface. The solar cell element receives light exiting from the light exit surface of the light guide. The spectral sensitivity of the solar cell element at the peak wavelength of the emission spectrum of the optical functional material having the longest peak wavelength of the emission spectrum among the plurality of optical functional materials is higher than the spectral sensitivity of the solar cell element at peak wavelengths of the emission spectrums of the other optical functional materials contained in the light guide.

### TECHNICAL FIELD

The present invention relates to a solar cell module and photovoltaic power generation device.

The present application claims priority to Japanese Patent Application No. 2011-208030 filed in Japan on Sep. 22, 2011, the contents of which are incorporated herein by reference.

### BACKGROUND ART

A photovoltaic power generation device described in PTL 1 is one of known photovoltaic power generation devices that produce electrical power by making light having propagated through a light guide incident on a solar cell element disposed on an end face of the light guide. The photovoltaic power generation device disclosed by PTL 1 is a window-type photovoltaic power generation device that uses the light guide as a window. In the photovoltaic power generation device according to PTL 1, part of sunlight incident on one principal plane of the light guide is made propagate through the light guide to be directed to solar cell element. The surface of the light guide has a fluorescent substance applied thereon, so that the fluorescent substance is excited by sunlight incident on the light guide. Light emitted by the fluorescent substance (fluorescent light) propagates through the light guide to be incident on the solar cell element, causing generation of electrical power.

### CITATION LIST

### Patent Literature

PTL 1: Japanese Unexamined Patent Application Publication No. 3-273686

### SUMMARY OF INVENTION

### Technical Problem

With the photovoltaic power generation device disclosed by PTL 1, only a small portion of sunlight incident on the light guide is used for excitation of fluorescent substances. Most part of sunlight incident on the light guide passes through the light guide and does not contribute to power generation. The photovoltaic power generation device accordingly does not provide high generation efficiency.

An object of an aspect of the present invention is to provide a solar cell module having high generation efficiency and a photovoltaic power generation device using the same.

### Solution to Problem

A solar cell module according to an aspect of the present invention includes: a light guide that has a light incident surface and a light exit surface having an area smaller than the light incident surface and that contains a plurality of optical functional materials, wherein part of external light incident on the light incident surface is absorbed by the plurality of optical functional materials, Foerster energy transfer occurs among the plurality of optical functional materials, and light emitted by the optical functional material having a longest peak wavelength of an emission spectrum among the plurality of optical functional materials is collected to and exits from the light exit surface; and a solar cell element that receives the light exiting from the light exit surface; wherein a spectral sensitivity of the solar cell element at the peak wavelength of the emission spectrum of the optical functional material having the longest peak wavelength of the emission spectrum among the plurality of optical functional materials is higher than the spectral sensitivity of the solar cell element at peak wavelengths of the emission spectrum of any of other optical functional materials contained in the light guide.

Among the plurality of optical functional materials, one or more optical functional materials other than the optical functional material having the longest peak wavelength of the emission spectrum may include an optical functional material(s) having a fluorescence quantum yield of 80% or less.

The fluorescence quantum yield of the optical functional material having the longest peak wavelength of the emission spectrum may be higher than the fluorescence quantum yield of the other optical functional material(s) contained in the light guide.

The light guide may contain optical functional materials formed from inorganic materials as the plurality of optical functional materials.

The light guide may contain optical functional materials formed from quantum dots as the optical functional materials formed from inorganic materials.

The solar cell module according to an aspect of the invention may further include a reflective layer that reflects light propagating from inside the light guide to outside the light guide so as to direct the light toward the inside of the light guide, and the reflective layer may be provided with an air layer interposed between the reflective layer and the light guide or in direct contact with the light guide without an air layer.

The reflective layer may be a scattering reflective layer that reflects and scatters incident light.

The light guide may include a transparent light guide and the plurality of optical functional materials dispersed in the transparent light guide.

The light guide may include a transparent light guide and an optical functional material layer which is disposed on a first principal plane of the transparent light guide and in which the plurality of optical functional materials are dispersed.

The solar cell module according to an aspect of the invention may further include a removable adhesive layer, and the transparent light guide and the optical functional material layer may be bonded together by the adhesive layer.

The light incident surface may be a flat plane.

The light guide may be a flat plate-like component, and the solar cell element may receive light exiting from an end face of the light guide that serves as the light exit surface.

At least part of the light incident surface may be a bent or curved plane.

The light guide may be formed as a curved plate-like component, and the solar cell element may receive light exiting from a curved end face of the light guide that serves as the light exit surface.

The light guide may be formed as a tubular component, and the solar cell element may receive light exiting from an end face of the light guide that serves as the light exit surface.

The light guide may be formed as a column-shaped component, and the solar cell element may receive light exiting from an end face of the light guide that serves as the light exit surface.

The solar cell module according to an aspect of the invention may further include a string-like connection member, and a plurality of module units each of which is a pair of the light guide and the solar cell element may be arranged alongside each other, and the plurality of module units may be flexibly connected with each other by the string-like connection member.

A plurality of module units each of which is a pair of the light guide and the solar cell element may be arranged alongside each other, and the plurality of module units may be connected such that they are spaced from each other.

A photovoltaic power generation device according to another aspect of the invention includes the inventive solar cell module.

### Advantageous Effects of Invention

According to aspects of the present invention, a solar cell module having high generation efficiency and a photovoltaic power generation device using the same are provided.

### BRIEF DESCRIPTION OF DRAWINGS

FIG. 1 is a schematic perspective view of a solar cell module according to a first embodiment of the invention.

FIG. 2 is a cross-sectional view of the solar cell module.

FIG. 3 shows the absorption characteristics of fluorescent substances.

FIG. 4 shows the absorption characteristics of fluorescent substances.

FIG. 5 shows the emission characteristics of fluorescent substances.

FIG. 6 shows the emission characteristics of fluorescent substances.

FIG. 7A describes energy transfer by photoluminescence.

FIG. 7B describes Foerster energy transfer.

FIG. 8A is a diagram describing how Foerster energy transfer occurs.

FIG. 8B illustrates Foerster energy transfer.

FIG. 9 shows the spectral sensitivity curve of an amorphous silicon solar cell with the emission spectrum of a first fluorescent substance, the emission spectrum of a second fluorescent substance, and the emission spectrum of a third fluorescent substance.

FIG. 10 shows the spectral sensitivity curves of various kinds of solar cell available for use as the solar cell element.

FIG. 11 shows the energy conversion efficiency of the solar cells shown in FIG. 10.

FIG. 12 is a cross-sectional view of a light guide employed in the solar cell module according to a second embodiment.

FIG. 13 is a cross-sectional view showing another exemplary structure of the light guide in the second embodiment.

FIG. 14 is a cross-sectional view showing the structure of primary components of the light guide.

FIG. 15 shows the emission spectrum of optical functional materials and the spectral sensitivity of the solar cell element used in the solar cell module according to a third embodiment.

FIG. 16 shows the emission spectrum of optical functional materials and the spectral sensitivity of the solar cell element used in the solar cell module according to a fourth embodiment.

FIG. 17 schematically illustrates the solar cell module according to a fifth embodiment.

FIG. 18 schematically illustrates the solar cell module according to a sixth embodiment.

FIG. 19 schematically illustrates the solar cell module according to a seventh embodiment.

FIG. 20 generally shows the configuration of a photovoltaic power generation device.

### DESCRIPTION OF EMBODIMENTS

### First Embodiment

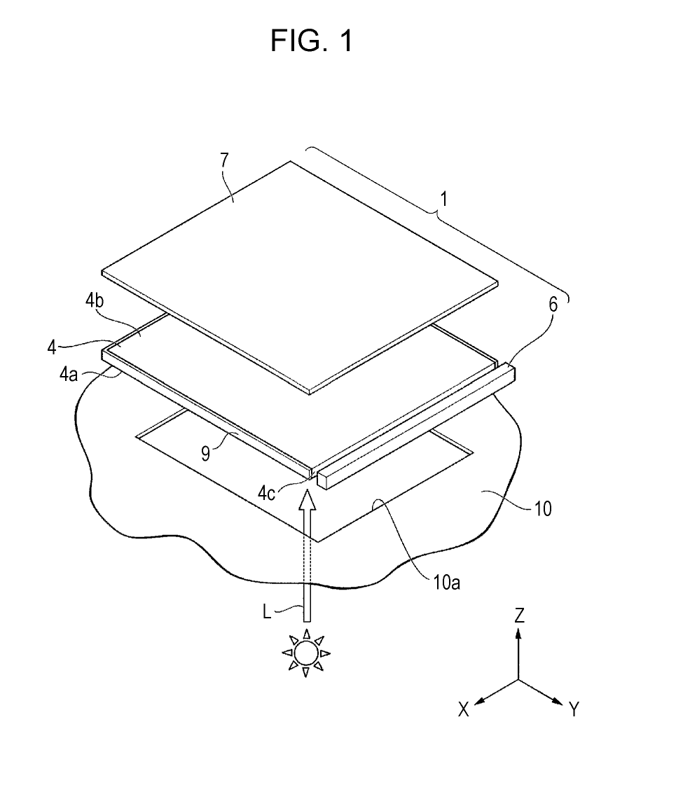

FIG. 1 is a schematic perspective view of a solar cell module 1 according to a first embodiment of the invention.

The solar cell module 1 includes a light guide 4 (fluorescent light guide), a solar cell element 6 for receiving light exiting from a first end face 4c of the light guide 4, and a frame 10 holding the light guide 4 and the solar cell element 6 together.

The light guide 4 has a first principal plane 4a to serve as the light incident surface, a second principal plane 4b positioned on the opposite side of the first principal plane 4a, and a first end face 4c to serve as the light exit surface.

The light guide 4 is a substantially rectangular, plate-shaped component having the first principal plane 4a and the second principal plane 4b, which are vertical to the Z-axis, or parallel to the X-Y plane. The light guide 4 is produced by dispersing multiple kinds of optical functional material in a substrate (a transparent substrate) made of an organic or inorganic material having high transparency, such as acrylic resin, polycarbonate resin, or glass. Examples of optical functional material include a fluorescent substance that absorbs ultraviolet light or visible light and emits visible light or infrared light, and a non-luminous material that absorbs ultraviolet light or visible light to become excited but deactivates without emitting light. At least one of the multiple kinds of optical functional material is a fluorescent substance. Light emitted by the fluorescent substance propagates through the light guide 4 and exits from the first end face 4c to be utilized for power generation in the solar cell element 6.

Visible light is light in the wavelength range from 380 nm to 750 nm; ultraviolet light is light in the wavelength range below 380 nm; and infrared light is light in the wavelength range above 750 nm.

In order to effectively take in external light, the material of the substrate (transparent substrate) of the light guide 4 desirably has transmissivity to light of wavelengths of 400 nm and shorter. For example, a material having transmittance of 90% or more, more preferably 93% or more, for light in the wavelength range between 360 nm and 800 nm is suitable. For instance, a silicon resin substrate, quartz substrate, or PMMA resin substrate such as Acrylite® of Mitsubishi Rayon Co., Ltd. are suited as they have high transparency for light of a wide wavelength range.

The first principal plane 4a and second principal plane 4b of the light guide 4 are flat planes generally parallel to the X-Y plane. On the end faces of the light guide 4 except the first end face 4c, a reflective layer 9 is provided with an air layer interposed or in direct contact with the light guide 4 without an air layer. The reflective layer 9 reflects off light traveling from inside the light guide 4 to outside the light guide 4 (light emitted from fluorescent substance) so as to direct the light toward the inside of the light guide 4. On the second principal plane 4b of the light guide 4, a reflective layer 7 is provided with an air layer interposed or in direct contact with the light guide 4 without an air layer. The reflective layer 7 reflects off light traveling from inside the light guide 4 to outside the light guide 4 (light emitted from fluorescent substance) or light that has entered from the first principal plane 4a but exit from the second principal plane 4b without being absorbed by optical functional materials so as to direct the light toward the inside of the light guide 4.

The reflective layers 7 and 9 may be reflective layers made of metal film such as silver and aluminum, or reflective layers formed from a dielectric multilayer film, such as enhanced specular reflector (ESR) reflective film (manufactured by 3M). The reflective layers 7 and 9 may be specular reflective layers that specularly reflect incident light or scattering reflective layers that reflect and scatter incident light. When the reflective layer 7 is a scattering reflective layer, the amount of light traveling directly toward the solar cell element 6 increases, leading to improved efficiency of light collection to the solar cell element 6 and hence greater power production. Additionally, since reflected light is scattered, variations in power production with time or season are evened out. For a scattering reflective layer, micro form polyethylene-terephthalate (PET) (manufactured by Furukawa Electric Co., Ltd.) may be employed, for example.

The solar cell element 6 is disposed such that its light receiving surface faces the first end face 4c of the light guide 4. Preferably, the solar cell element 6 is optically bonded to the first end face 4c. The solar cell element 6 may be any of well-known solar cells, including silicon-based, compound-based, and organic solar cells. A compound-based solar cell using a compound semiconductor is particularly well-suited for the solar cell element 6 because it is capable of efficient power generation.

While FIG. 1 shows an example where the solar cell element 6 is provided on only one end face of the light guide 4, the solar cell element 6 may be provided on more than one end face of the light guide 4. If the solar cell element 6 is provided on some end faces (one, two, or three sides) of the light guide 4, it is preferable to dispose a reflective layer 9 on end face(s) on which no solar cell element is provided.

The frame 10 has a transmissive surface 10a which transmits light L on the plane opposite the first principal plane 4a of the light guide 4. The transmissive surface 10a may be an opening in the frame 10 or a transparent material such as glass embedded in an opening in the frame 10. A part of the first principal plane 4a of the light guide 4 that overlaps the transmissive surface 10a of the frame 10 when seen in the Z-direction represents the light incident surface of the light guide 4. The first end face 4c of the light guide 4 represents the light exit surface of the light guide 4.

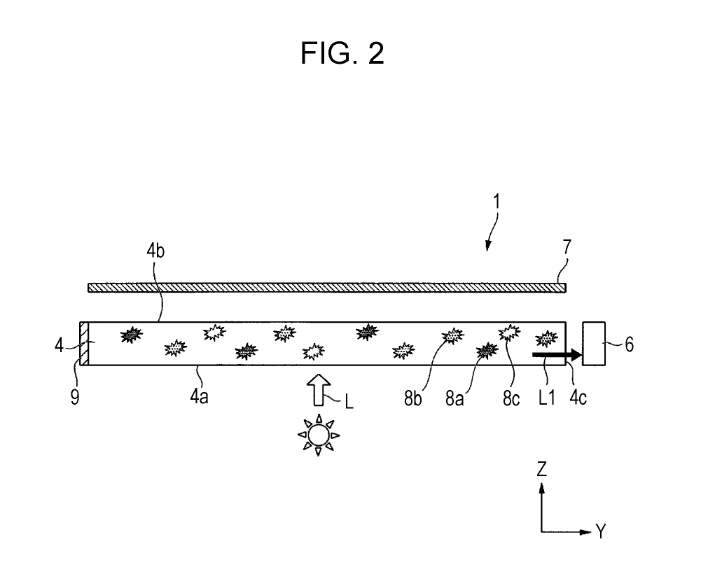

FIG. 2 is a cross-sectional view of the solar cell module 1.

In this embodiment, multiple kinds of fluorescent substance having different absorption wavelength ranges (in FIG. 2, a first fluorescent substance 8a, a second fluorescent substance 8b, and a third fluorescent substance 8c, for example) are dispersed in the light guide 4 as optical functional materials. The first fluorescent substance 8a absorbs ultraviolet light and emits blue fluorescent light. The second fluorescent substance 8b absorbs blue light and emits green fluorescent light. The third fluorescent substance 8c absorbs green light and emits red fluorescent light. The first fluorescent substance 8a, the second fluorescent substance 8b, and the third fluorescent substance 8c are added during molding of PMMA resin, for example. The mixing ratio of the first fluorescent substance 8a, the second fluorescent substance 8b, and the third fluorescent substance 8c is shown below, where the mixing ratio is represented as a volume percentage relative to PMMA resin.

The first fluorescent substance 8a: Lumogen F Violet 570 (a trade name) manufactured by BASF 0.02%; the second fluorescent substance 8b: Lumogen F Yellow 083 (a trade name) manufactured by BASF 0.02%; and the third fluorescent substance 8c: Lumogen F Red 305 (a trade name) manufactured by BASF 0.02%.

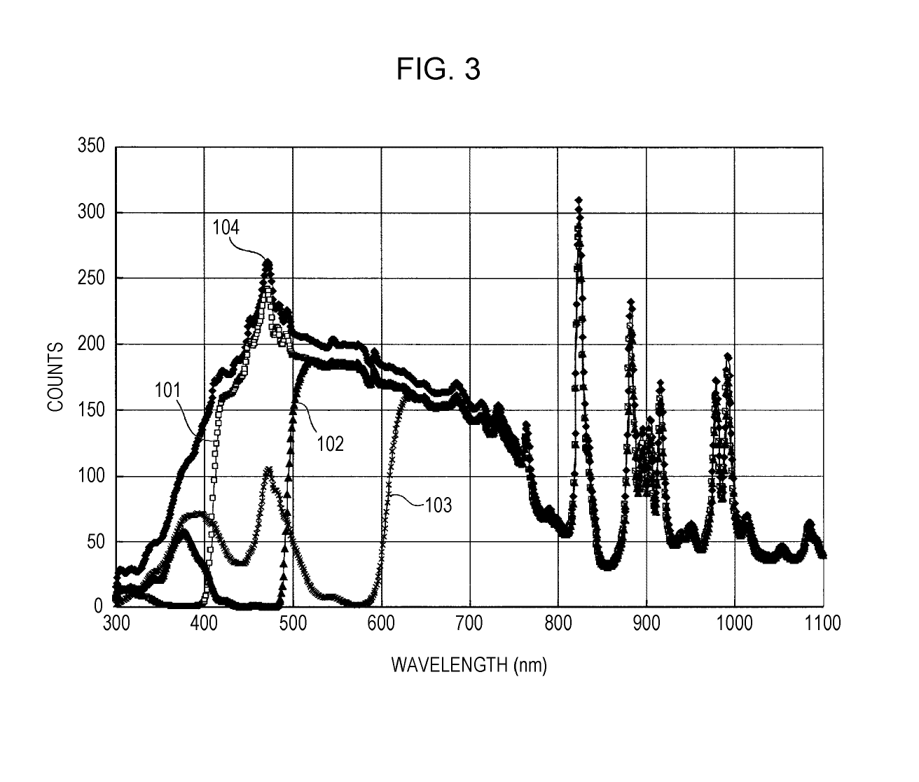

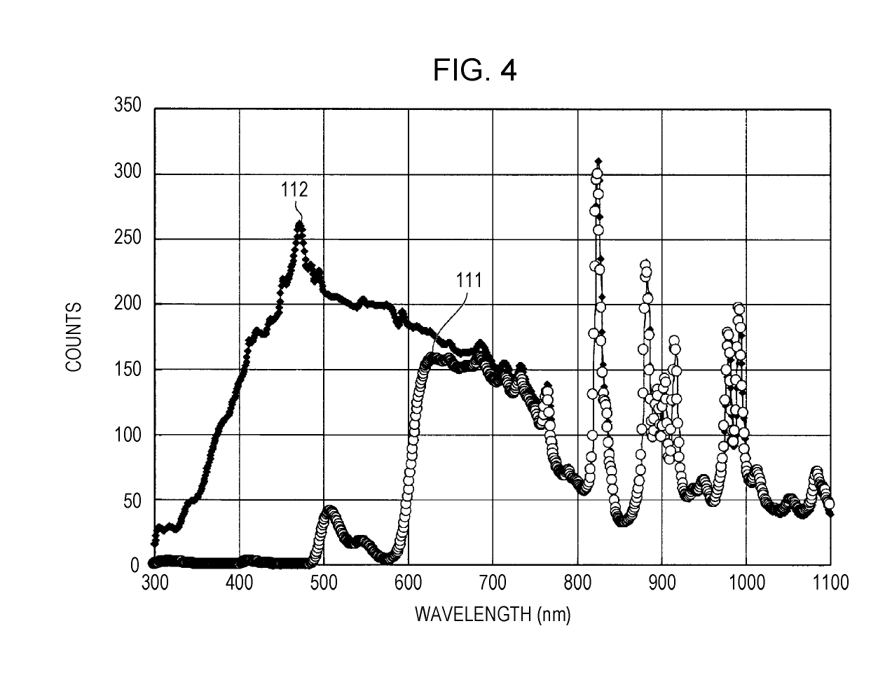

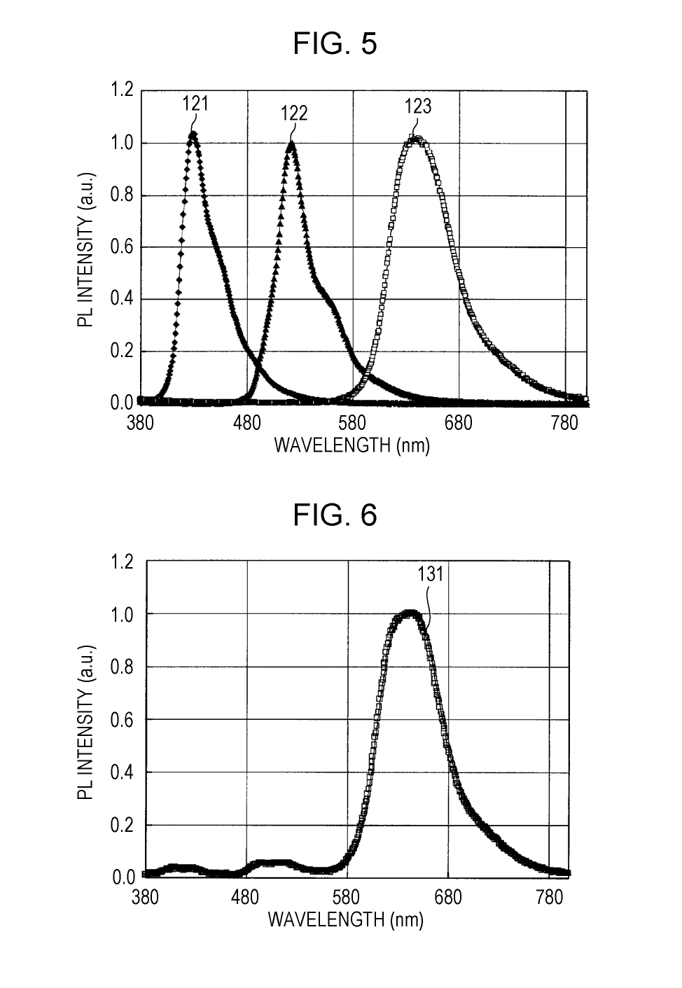

FIGS. 3 to 6 show the light emission and absorption characteristics of the first fluorescent substance 8a, the second fluorescent substance 8b, and the third fluorescent substance 8c. In FIG. 3, reference numeral 101 represents the spectrum of sunlight with ultraviolet light absorbed by the first fluorescent substance 8a. Reference numeral 102 represents the spectrum of sunlight with blue light absorbed by the second fluorescent substance 8b. Reference numeral 103 represents the spectrum of sunlight with green light absorbed by the third fluorescent substance 8c. Reference numeral 104 represents the spectrum of sunlight. In FIG. 4, reference numeral 111 represents the spectrum of sunlight with ultraviolet light, blue light, and green light absorbed by the first fluorescent substance 8a, the second fluorescent substance 8b, and the third fluorescent substance 8c. Reference numeral 112 represents the spectrum of sunlight. In FIG. 5, reference numeral 121 represents the emission spectrum of the first fluorescent substance 8a; reference numeral 122 represents the emission spectrum of the second fluorescent substance 8b; and reference numeral 123 represents the emission spectrum of the third fluorescent substance 8c. In FIG. 6, reference numeral 131 represents the spectrum of light exiting from the first end face of the light guide containing the first fluorescent substance 8a, the second fluorescent substance 8b, and the third fluorescent substance 8c.

As shown in FIGS. 3 and 4, the first fluorescent substance 8a absorbs light of wavelengths approximately below 420 nm. The second fluorescent substance 8b absorbs light of wavelengths approximately from 420 nm to 520 nm. The third fluorescent substance 8c absorbs light of wavelengths approximately from 520 nm to 620 nm. Of sunlight incident on the light guide, almost all of light having wavelengths below 620 nm is absorbed by the first fluorescent substance 8a, the second fluorescent substance 8b, and the third fluorescent substance 8c. In the sunlight spectrum, light of wavelengths below 620 nm accounts for about 48%. Hence, 48% of light incident on the light incident surface of the light guide is absorbed by the first fluorescent substance 8a, the second fluorescent substance 8b, and the third fluorescent substance 8c contained in the light guide.

As illustrated in FIG. 5, the emission spectrum of the first fluorescent substance 8a has a peak wavelength at 430 nm; the emission spectrum of the second fluorescent substance 8b has a peak wavelength at 520 nm; and the emission spectrum of the third fluorescent substance 8c has a peak wavelength at 630 nm. As shown in FIG. 6, however, the spectrum of light exiting from the first end face of the light guide containing the first fluorescent substance 8a, the second fluorescent substance 8b, and the third fluorescent substance 8c has a peak wavelength only at a wavelength corresponding to the peak wavelength of the emission spectrum of the third fluorescent substance 8c (630 nm), and does not have peak wavelengths at wavelengths corresponding to the peak wavelength of the emission spectrum of the first fluorescent substance 8a (430 nm) and the peak wavelength of the emission spectrum of the second fluorescent substance 8b (520 nm).

Disappearance of the peaks of the emission spectrums corresponding to the first fluorescent substance 8a and the second fluorescent substance 8b can be attributed to photoluminescence (PL) energy transfer between fluorescent substances or Foerster energy transfer between fluorescent substances (fluorescence resonance energy transfer). Photoluminescence energy transfer is caused by fluorescent light emitted by one fluorescent substance being utilized as excitation energy for another fluorescent substance. The Foerster mechanism is direct movement of excitation energy between two adjacent fluorescent substances due to resonance between electrons without undergoing the process of light emission and absorption like photoluminescence. Because Foerster energy transfer between fluorescent substances takes place without involving the light emission and absorption process, energy loss is small under optimal conditions. It thus contributes to improvement in generation efficiency of a solar cell module. In order to reduce energy loss and achieve efficient power generation, this embodiment provides the first fluorescent substance 8a, the second fluorescent substance 8b, and the third fluorescent substance 8c in high density so that Foerster energy transfer occurs among the fluorescent substances.

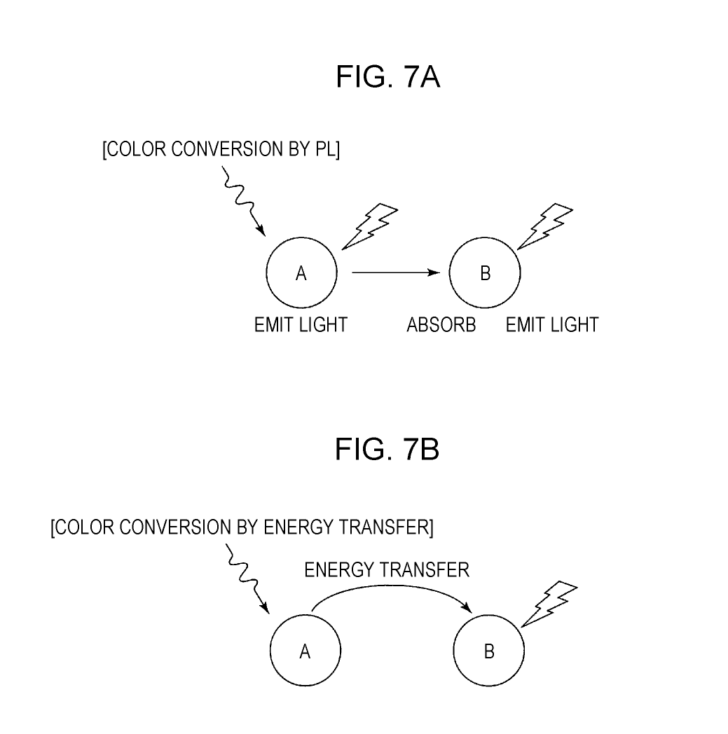

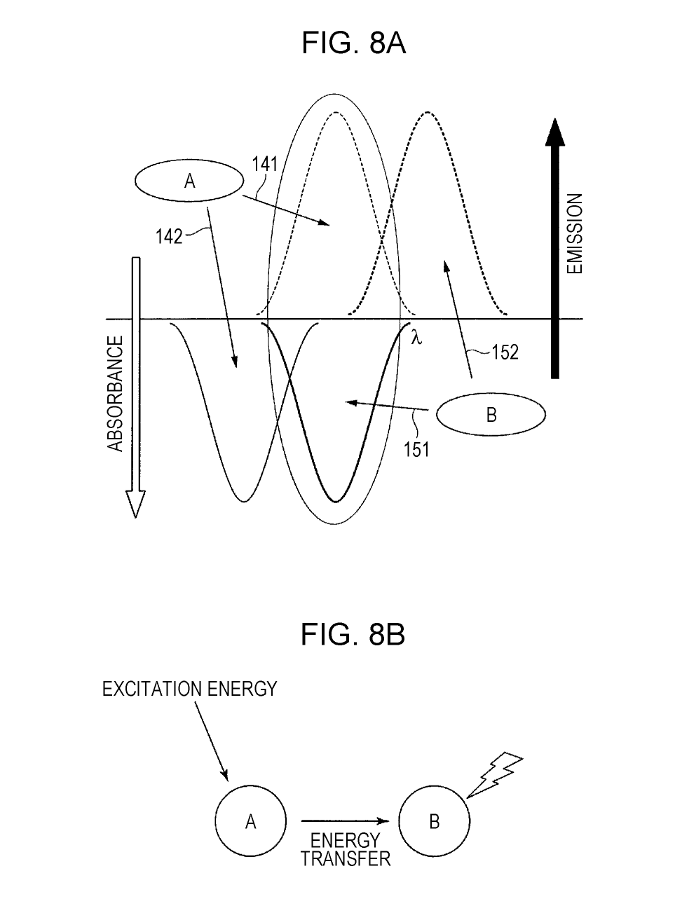

Now turning to FIGS. 7A to 8B, the Foerster mechanism is described. FIG. 7A describes photoluminescence energy transfer. FIG. 7B describes Foerster energy transfer. FIG. 8A is a diagram describing how Foerster energy transfer occurs. FIG. 8B describes Foerster energy transfer.

As shown in FIG. 7B, in a fluorescent substance composed of organic molecules or inorganic nanoparticles, energy transfer can occur due to the Foerster mechanism from molecule A in excited state to molecule B in ground state. In a fluorescent substance, if energy transfer to molecule B occurs when molecule A is excited, molecule B emits light. Such energy transfer is dependent on the distance between the molecules, the emission spectrum of molecule A, and the absorption spectrum of molecule B. Assuming that molecule A is the host molecule and molecule B is the guest molecule, velocity constant in energy transfer (the possibility of transfer) is represented as equation (1)

$$\begin{matrix}[ Equation 1 ] & \\ {k}_{H \to G} = \frac{9000 {K}^{2} ln 10}{128 {π}^{5} {n}^{4} N {τ}_{0} {R}^{6}} \int \frac{{f}_{H}^{′} ( v ) ɛ ( v ) d v}{{v}^{4}} & ( 1 )\end{matrix}$$

In equation (1), ν is frequency, f′_{H}(ν) is the emission spectrum of the host molecule A, ∈(ν) is the absorption spectrum of the guest molecule B, N is the Avogadro constant, n is refractive index, τ₀ is the fluorescence lifetime of the host molecule A, R is the distance between the molecules, and K² is transition dipole moment (⅔ when randomly set).

When the velocity constant is large, energy transfer is easy to occur between fluorescent substances. To obtain a large velocity constant, it is desirable that the following conditions be satisfied.

[1] Overlap between the emission spectrum of the host molecule A and the absorption spectrum of the guest molecule is large;

[2] The guest molecule B has a large absorption coefficient; and

[3] The distance between the host molecule A and the guest molecule B is small.

Condition [1] describes ease of resonance between two adjacent fluorescent substances. For example, when the peak wavelength of the emission spectrum 141 of the host molecule A is close to the peak wavelength of the absorption spectrum 151 of guest molecule B as shown in FIG. 8A, Foerster energy transfer is easy to occur. When the guest molecule B in ground state is present near the host molecule A in excited state as illustrated in FIG. 8B, the wave function of the guest molecule A changes due to resonant properties, making host molecule A in ground state and guest molecule B in excited state. This causes energy transfer between host the molecule A and the guest molecule B, resulting in the guest molecule B emitting light. In FIG. 8A, reference numeral 142 indicates the absorption spectrum of the host molecule A while reference numeral 152 indicates the emission spectrum of the guest molecule B.

As to condition [3], an inter-molecular distance that causes Foerster energy transfer is typically about 10 nm. Depending on the condition, energy transfer can occur even with an inter-molecular distance of about 20 nm. With the mixing ratio of the first, second, and third fluorescent substances shown above, the distance between fluorescent substances is shorter than 20 nm. Thus, Foerster energy transfer is sufficiently able to occur. Also, the emission and absorption spectrums of the first fluorescent substance, the second fluorescent substance, and the third fluorescent substance shown in FIGS. 3 and 5 sufficiently satisfy the condition [1]. Consequently, energy transfer from the first fluorescent substance to the second fluorescent substance and energy transfer from the second fluorescent substance to the third fluorescent substance occur, causing cascaded energy transfer in the order of the first fluorescent substance, the second fluorescent substance, and the third fluorescent substance.

In the light guide, despite inclusion of fluorescent substances having three different emission spectrums (the first, second, and third fluorescent substances), light emission occurs substantially only in the third fluorescent substance because of Foerster energy transfer. The luminescent quantum efficiency of the third fluorescent substance is 92%, for example. Accordingly, by mixing the first fluorescent substance, the second fluorescent substance, and the third fluorescent substance in the light guide, light in a wavelength range up to 620 nm can be absorbed and red light having the peak wavelength at 630 nm can be generated with 92% efficiency.

Such energy transfer is considered to be a phenomenon specific to organic fluorescent substances and generally not occur in inorganic fluorescent substances, but it is known that energy transfer occurs between inorganic materials or between an inorganic material and an organic material due to the Foerster mechanism in some fluorescent substances composed of inorganic nanoparticles, such as quantum dots.

For example, energy transfer occurs between quantum dots of a ZnO—MgZnO core-shell structure having two different sizes. Since quantum dots having a dimensional ratio of 1:√2 have an exciton level that causes resonance, energy transfer occurs from the smaller quantum dot to the larger quantum dot between, for example, a quantum dot having a radius of 3 nm (peak wavelength of the emission spectrum: 350 nm) and a quantum dot having a radius of 4.5 nm (peak wavelength of the emission spectrum: 357 nm). Energy transfer also occurs between two quantum dots of a CdSe—ZnS core-shell structure having different sizes. A Mn2+ doped ZnSe quantum dot having a diameter of 8 nm to 9 nm has emission peaks at 450 nm and 580 nm, and agrees well with the light absorption spectrum of a ring-opening Spiropyran molecule (SPO open; Merocynanine form) obtained by radiating 1′,3′-dihydro-1′,3′,3′-trimethyl-6-nitrospiro[2H-1-benzopyran-2,2′-(2H)-indole], which is a dye molecule, with ultraviolet light, resulting in energy transfer from the quantum dot to the dye molecule. In general, inorganic fluorescent substances have higher light resistance than organic fluorescent substances and thus are advantageous for long term use.

In a case where two kinds of fluorescent substance are mixed, fluorescent substance A typically first emits light with a certain efficiency, and the light is incident on fluorescent substance B, in which the light undergoes the light absorption and emission process to result in light emission from fluorescent substance B, as illustrated in FIG. 7A. Such photoluminescence energy transfer causes energy loss during the light emission process in fluorescent substance A and light absorption process in fluorescent substance B; energy transfer efficiency is low.

In contrast, in the Foerster energy transfer shown in FIG. 7B, only energy moves directly between fluorescent substances, so that energy transfer efficiency can be nearly 100% and energy transfer can efficiently take place.

In addition to light emission materials such as fluorescent substance, Foerster energy transfer also occurs in a non-luminous material which is excited by external light but deactivates without emitting light. The final power production depends on the fluorescence quantum yield of the guest molecule and is not dependent on the fluorescence quantum yield of the host molecule. Therefore, the power production would be the same if only the guest molecule is formed from a fluorescent substance having a high fluorescence quantum yield and the host molecule is formed from a fluorescent substance having a low fluorescence quantum yield or a non-luminous material that does not emit fluorescent light. Thus, compared to a case where high fluorescence quantum yield is required for all fluorescent substances such as for photoluminescence energy transfer, the material of the host molecule can be selected from a wide range of options.

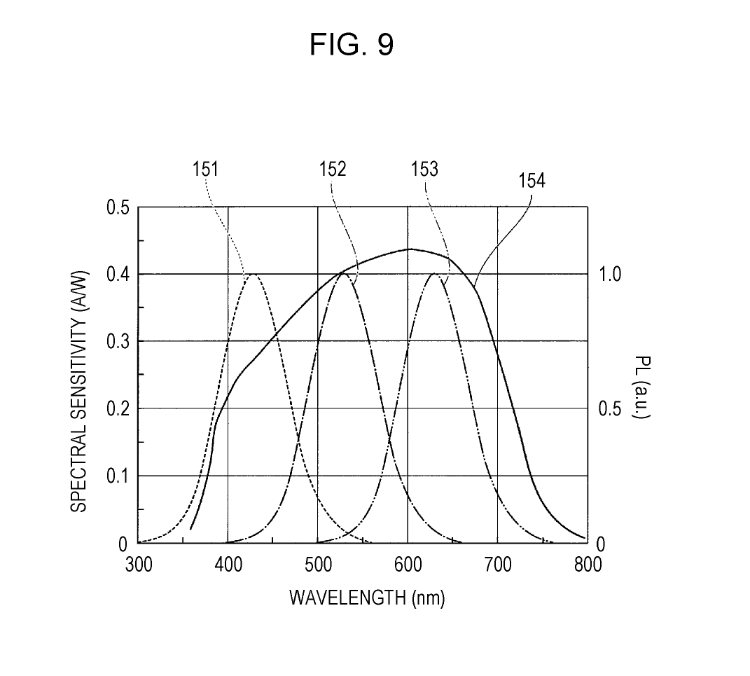

FIG. 9 shows a spectral sensitivity curve 154 of an amorphous silicon solar cell, an example of the solar cell element 6, with the emission spectrum 151 of the first fluorescent substance, the emission spectrum 152 of the second fluorescent substance, and the emission spectrum 153 of the third fluorescent substance.

The spectrum of light L1 that exits from the first end face 4c of the light guide 4 substantially matches the emission spectrum of the third fluorescent substance 8c. The solar cell element 6 accordingly should have high sensitivity around the peak wavelength of the emission spectrum of the third fluorescent substance 8c (630 nm). As illustrated in FIG. 9, the amorphous silicon solar cell has the highest spectral sensitivity for light of wavelengths around 600 nm. Comparing the spectral sensitivity of the amorphous silicon solar cell at the peak wavelengths of the emission spectrums of the first, second, and third fluorescent substance, the spectral sensitivity of the amorphous silicon solar cell at the peak wavelength of the emission spectrum of the third fluorescent substance, having the longest peak wavelength of the emission spectrum, is greater than the spectral sensitivity of the amorphous silicon solar cell at the peak wavelengths of the emission spectrums of the other fluorescent substances (the first and second fluorescent substances) contained in the light guide. Accordingly, use of an amorphous silicon solar cell for the solar cell element 6 enables highly efficient power generation.

For example, the amount of power generated by making sunlight having an air mass (AM) of 1.5 incident vertically in Z-direction to a square light guide formed from PMMA resin 30 cm long, 30 cm wide, and 5 mm thick with an amorphous silicon solar cell disposed on an end face of the light guide was measured as follows.

The material and quantity of the first fluorescent substance 8a, the second fluorescent substance 8b, and the third fluorescent substance 8c contained in the light guide 4 are as mentioned above, and they have the emission and absorption spectrums shown in FIGS. 3 to 6. The refractive index of the light guide 4 is 1.49, the same as PMMA resin or its material, because the first fluorescent substance 8a, the second fluorescent substance 8b, and the third fluorescent substance 8c are present in small quantities. The first fluorescent substance 8a, the second fluorescent substance 8b, and the third fluorescent substance 8c all have the fluorescence quantum yield of 95%. The amorphous silicon solar cell has the spectral characteristics shown in FIG. 9. “Air mass” means the length of the path traveled by direct sunlight incident on the earth's atmosphere. The length of the path is expressed as a ratio to the length of the path traveled by direct sunlight vertically incident on the atmosphere of the standard atmospheric pressure (standard barometric pressure: 1013 hPa), defined as AM 1.0. The luminous energy of sunlight of AM 1.5 is 100 mW/cm².

When sunlight of AM 1.5 is vertically incident on the light guide 4, 48% of the incident light is absorbed by the first fluorescent substance 8a, the second fluorescent substance 8b, and the third fluorescent substance 8c, and cascaded energy transfer occurs in the order of the first fluorescent substance 8a, the second fluorescent substance 8b, and the third fluorescent substance 8c due to the Foerster mechanism, resulting in the third fluorescent substance 8c emitting fluorescent light. The fluorescent light emitted by the third fluorescent substance 8c propagates through the light guide 4 to exit from the first end face 4c. The proportion of light L1 that does not totally reflect in the light guide 4 due to the difference in the reflective indices of the light guide 4 and the surrounding air layer and leaks outside is 25% and light lost during propagation in the light guide 4 is 5%; light L1 that exits from the first end face 4c of the light guide 4 accounts for 70% of the light incident on the light incident surface 4a of the light guide 4. The energy conversion efficiency of the amorphous silicon solar cell in a wavelength range around the peak wavelength of the emission spectrum of the third fluorescent substance 8c is 22%. The power produced under the conditions was 6.32 W.

The kind of solar cell employed as the solar cell element 6 depends on the wavelength of light incident on the solar cell element. While amorphous silicon solar cell is used as the solar cell element 6 in FIG. 9, this is not a limitation.

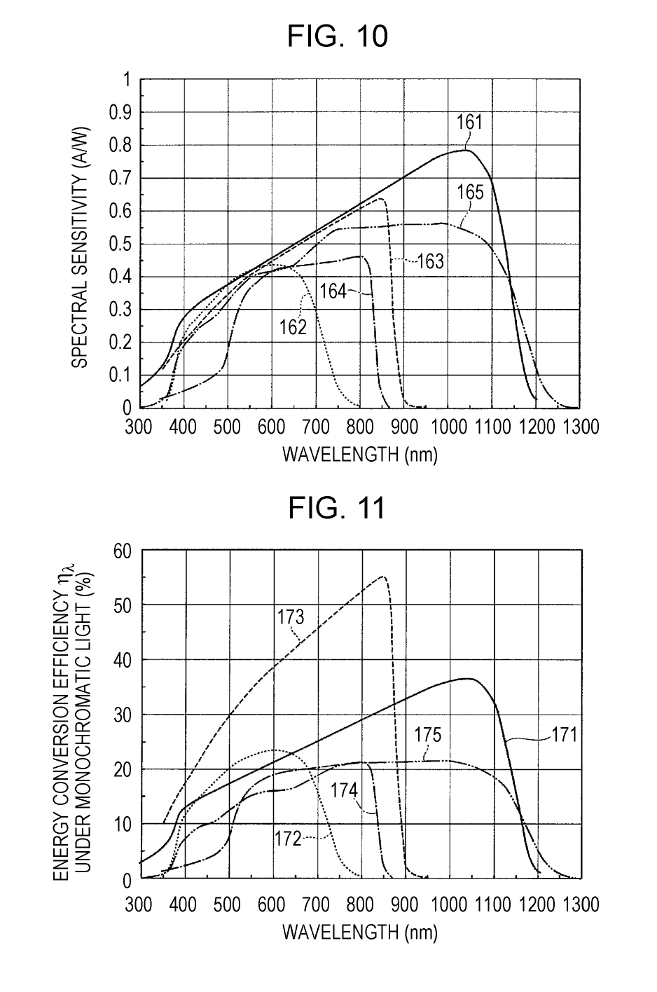

FIG. 10 shows the spectral sensitivity curves of different kinds of solar cell available for use as the solar cell element 6. FIG. 11 shows the energy conversion efficiency η_{λ} of the solar cells. In FIG. 10, reference numeral 161 indicates mono-crystalline silicon (c-Si) solar cell; reference numeral 162 indicates amorphous silicon solar cell (single-junction, a-Si(1j)); reference numeral 163 indicates gallium arsenide solar cell (single-junction, GaAs(1j)); reference numeral 164 indicates cadmium tellurium (CdTe) solar cell; and reference numeral 165 indicates Cu(m, Ga)(Se, S)₂(CIGSSe) solar cell. In FIG. 11, reference numeral 171 indicates mono-crystalline silicon (c-Si) solar cell; reference numeral 172 indicates amorphous silicon solar cell (single-junction, a-Si(1j)); reference numeral 173 indicates gallium arsenide solar cell (single-junction, GaAs(1j)); reference numeral 174 indicates cadmium tellurium (CdTe) solar cell; and reference numeral 175 indicates Cu(m, Ga)(Se, S)₂(CIGSSe) solar cell.

With the solar cells shown in FIGS. 10 and 11, the spectral sensitivity and energy conversion efficiency of the solar cells at the peak wavelength (630 nm) of the emission spectrum of the third fluorescent substance 8c, having the longest peak wavelength of the emission spectrum, are higher than the spectral sensitivity and energy conversion efficiency of the solar cells at the peak wavelengths of the emission spectrums of the other fluorescent substances (the first and second fluorescent substances 8a, 8b) contained in the light guide 4. Accordingly, use of these solar cells as the solar cell element 6 would enable highly efficient power generation.

For instance, when a mono-crystalline silicon solar cell (c-Si) was used for the solar cell element 6, the energy conversion efficiency of the mono-crystalline silicon solar cell in a wavelength range around the peak wavelength of emission spectrum of the third fluorescent substance 8c was 24% and the power production was 6.9 W. When a gallium arsenide solar cell (GaAs(1j)) was used for the solar cell element 6, the energy conversion efficiency of the gallium arsenide solar cell in a wavelength range around the peak wavelength of emission spectrum of the third fluorescent substance 8c was 40% and the power production was 11.5 W.

FIGS. 10 and 11 show examples of solar cells available for use as the solar cell element 6, though other kinds of solar cell may be employed of course. It is also possible to actively use solar cells of a type that cannot have high spectral sensitivity over the entire wavelength range of sunlight but has a very high spectral sensitivity to light of a particular narrow wavelength range, such as dye sensitized or organic solar cell, as the solar cell element 6.

As described, in the solar cell module 1 according to the first embodiment, part of external light L incident on the light incident surface 4a is absorbed by multiple kinds of optical functional material (the first fluorescent substance 8a, the second fluorescent substance 8b, the third fluorescent substance 8c), Foerster energy transfer is made to occur among the optical functional materials, and light L1 emitted by the optical functional material having the longest peak wavelength of the emission spectrum (the third fluorescent substance 8c) is collected to the first end face 4c of the light guide 4 to be incident on the solar cell element 6. The solar cell element 6 therefore may be formed of a solar cell having a very high spectral sensitivity in a limited narrow wavelength range, so that a solar cell module having high generation efficiency is realized.

### Second Embodiment

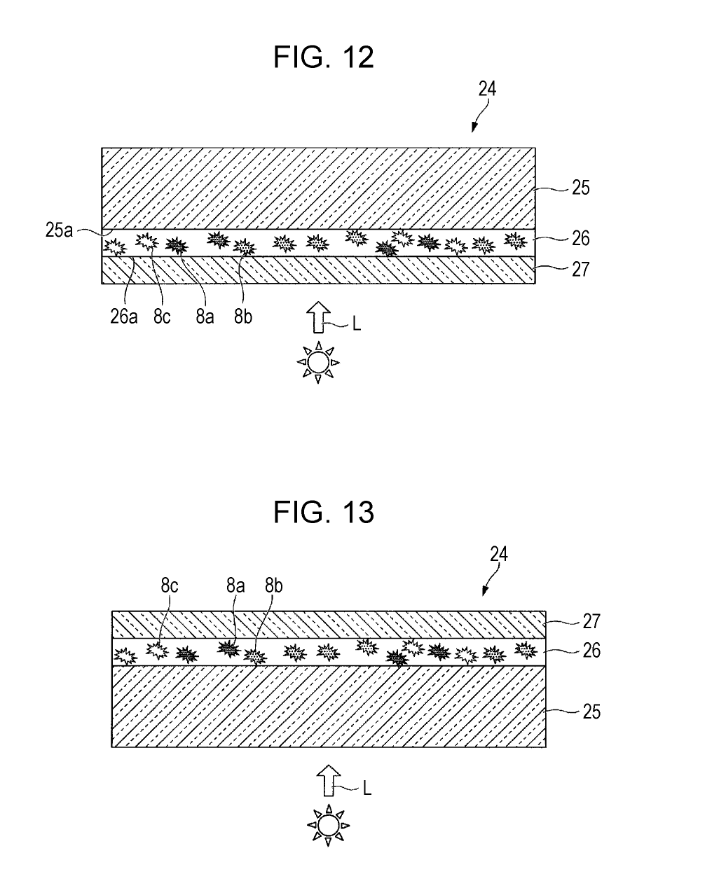

FIG. 12 is a cross-sectional view of a light guide (fluorescent light guide) 24 employed in the solar cell module according to a second embodiment of the invention. Except for the light guide 24, the solar cell module has the same configuration as the solar cell module 1 in the first embodiment. Thus, the structure of the light guide 24 is described here. Elements common to the solar cell module 1 in the first embodiment are denoted by the same reference signs and are not described in detail.

The light guide 24 includes a transparent light guide 25, a fluorescent film 26 bonded to a first principal plane 25a of the transparent light guide 25, and a transparent protective film 27 covering the fluorescent film 26.

The fluorescent film 26 is a film-shaped optical functional material layer in which the first fluorescent substance 8a, the second fluorescent substance 8b, and the third fluorescent substance 8c are dispersed as the optical functional materials described above. The fluorescent film 26 converts part of external light (e.g., sunlight) incident on the first principal plane 26a into fluorescent light and emits it toward the transparent light guide 25. The fluorescent film 26 may be produced by mixing the first fluorescent substance 8a, the second fluorescent substance 8b, and the third fluorescent substance 8c into PMMA resin all at the volume percentage of 0.2% relative to the PMMA resin and forming it into film of a 200 μm thickness, for example.

The transparent light guide 25 and the transparent protective film 27 may be made of organic or inorganic materials having high transparency, such as acrylic resin, polycarbonate resin, and glass. For example, the transparent light guide 25 may be a 5-mm-thick acrylic plate and the transparent protective film 27 may be PMMA resin film having a thickness of 200 μm. While in FIG. 12 the transparent protective film 27, the fluorescent film 26, and the transparent light guide 25 are disposed in this order from the incident side of the external light L, they may be disposed in the order of the transparent light guide 25, fluorescent film 26, and transparent protective film 27 from the incident side of the external light L as shown in FIG. 13.

The transparent light guide 25 and the transparent protective film 27 are formed from a material that does not contain optical functional material and has high transparency. Part of fluorescent light (light having a spectrum generally the same as the emission spectrum of the third fluorescent substance 8c shown in FIG. 5) emitted from the fluorescent film 26 propagates through the transparent light guide 25 and the transparent protective film 27 in total reflection toward the end face of the transparent light guide 25 and the transparent protective film 27. After exiting from the end face of the transparent light guide 25 and the transparent protective film 27, the light is incident on the solar cell element to be utilized for electrical power generation.

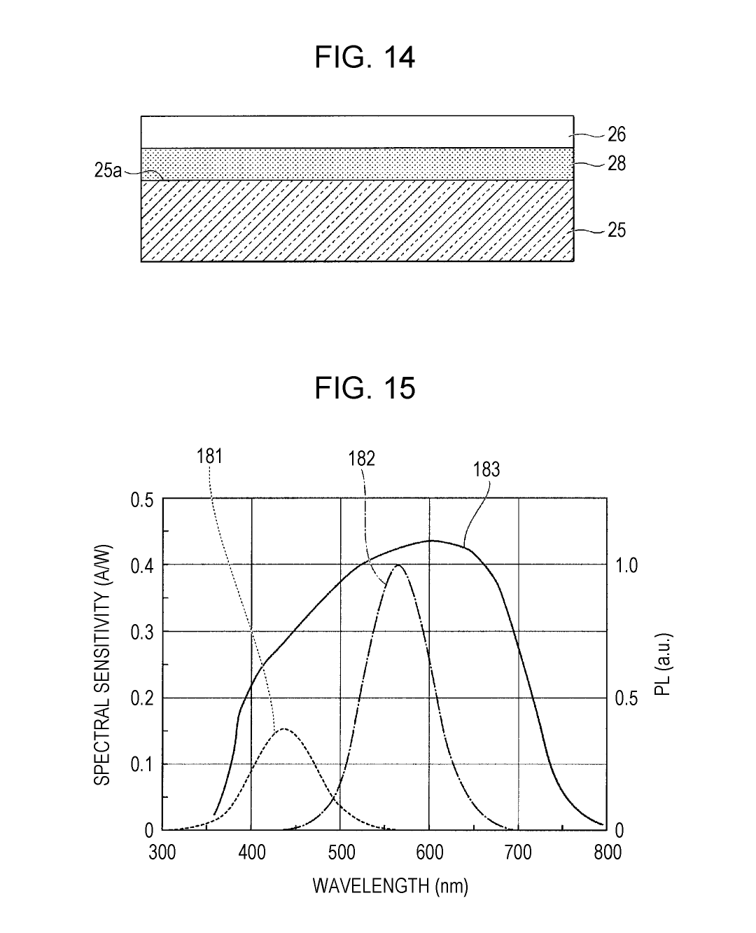

The fluorescent film 26 and the transparent light guide 25 are bonded together by a removable adhesive layer 28 as shown in FIG. 14. The fluorescent film 26 can be peeled from the transparent light guide 25 for replacement in case of breakage, deterioration, or adhesion of a foreign matter (such as dust or bird droppings) on it. The fluorescent film 26, adhesive layer 28, and transparent light guide 25 all have a refractive index of 1.49. Fluorescent light emitted by the fluorescent film 26 propagates through the fluorescent film 26, the adhesive layer 28, and the transparent light guide 25 with no loss. Accordingly, under similar conditions to the first embodiment, the power production measured 6.32 W, equivalent to the first embodiment. For the adhesive layer 28 having such features, Gelpoly (a trade name) of PANAC Co., Ltd. may be used for example.

In the light guide 24 thus structured, the fluorescent film 26 and the transparent light guide 25 are bonded together by the removable adhesive layer 28. This allows only the fluorescent film 26 to be peeled from the transparent light guide 25 and changed if the fluorescent film 26 is damaged or deteriorated, or some foreign matter (such as dust or bird droppings) adheres to it and the generation efficiency has lowered. This leads to reduced maintenance cost compared to an arrangement where the entire light guide is replaced.

### Third Embodiment

FIG. 15 shows the emission spectrum of optical functional materials and the spectral sensitivity of the solar cell element used in the solar cell module according to a third embodiment of the invention. In FIG. 15, reference numeral 181 represents the emission spectrum of a fourth fluorescent substance; reference numeral 182 represents the emission spectrum of a fifth fluorescent substance; and reference numeral 183 represents the spectral sensitivity curve of an amorphous silicon solar cell.

The solar cell module 1 according to the first embodiment uses three kinds of fluorescent substances (the first fluorescent substance 8a, second fluorescent substance 8b, and third fluorescent substance 8c) having high fluorescence quantum yields as optical functional materials contained in the light guide 4; whereas the solar cell module in the third embodiment uses a fourth fluorescent substance having low fluorescence quantum yield and a fifth fluorescent substance having high fluorescence quantum yield as optical functional materials contained in the light guide. The fourth fluorescent substance serves as the host molecule while the fifth fluorescent substance serves as the guest molecule, so that Foerster energy transfer occurs between the fourth and fifth fluorescent substances to cause substantially only the fifth fluorescent substance, or the guest molecule, to emit light.

The fourth fluorescent substance may be NPB (N,N-di(naphthalene-1-yl)-N,N-diphenyl-benzidene), for example. The fourth fluorescent substance has the fluorescence quantum yield of 42% and the peak wavelength of its emission spectrum is 430 nm. The fifth fluorescent substance may be rubrene, for example. The fifth fluorescent substance has a fluorescence quantum yield as high as near 100%, and the peak wavelength of its emission spectrum is 560 nm. The content percentage of the fifth fluorescent substance relative to the fourth fluorescent substance is 2%. The light guide in this embodiment may be produced by forming a film of an optical functional material layer containing the fourth and fifth fluorescent substances in a thickness of 5 μm on the first principal plane of a transparent light guide made of a 2-mm-thick glass substrate and forming a film of parylene having a thickness of 1 μm on the surface of the optical functional material layer as a transparent protective film, for example.

The solar cell element is an amorphous silicon solar cell. Comparing the spectral sensitivity of the amorphous silicon solar cell at the peak wavelengths of the emission spectrums of the fourth and fifth fluorescent substances, the spectral sensitivity of the amorphous silicon solar cell at the peak wavelength in the emission spectrum of the fifth fluorescent substance, having the longer peak wavelength of the emission spectrum, is greater than the spectral sensitivity of the amorphous silicon solar cell at the peak wavelength of the emission spectrum of the other fluorescent substance (the fourth fluorescent substance) contained in the light guide. Accordingly, use of an amorphous silicon solar cell for the solar cell element enables highly efficient power generation.

The power production measured 5.6 W under similar conditions to the first embodiment. Assuming that Foerster energy transfer does not occur and excitation energy from the fourth fluorescent substance transfers to the fifth fluorescent substance through the photoluminescence light emission and absorption process, the power production would be 4 W. Thus, the power production is higher by about 40% than the case where the photoluminescence process takes place.

In this embodiment, the fourth fluorescent substance serving as the host molecule has a very low fluorescence quantum yield of 42%. However, the final power production with Foerster energy transfer is determined by the fluorescence quantum yield of the guest molecule and is not dependent on the fluorescence quantum yield of the host molecule. Accordingly, only the guest molecule being composed of a fluorescent substance having high fluorescence quantum yield would result in the same power production even if the host molecule is composed of a fluorescent substance having low fluorescence quantum yield. Since a fluorescent substance is generally used as a luminous material, fluorescent substances having low fluorescence quantum yield cannot be employed; however, in the case of direct transfer of only energy without light emission as in this embodiment, fluorescent substances having low fluorescence quantum yield can be used because the final power production is the same even if fluorescence quantum yield is low. As many of fluorescent substances having high fluorescence quantum yield are generally expensive and have low light resistance and a short life, they can lead to high maintenance costs. In contrast, fluorescent substances having low fluorescence quantum yield are often inexpensive, available from a wide range of material options, high in light resistance, and have a long life, so that use of such fluorescent substances can save maintenance costs.

The fluorescent substance used for the fourth fluorescent substance preferably has a fluorescence quantum yield of less than 90%, more preferably 80% or less. As the lifetime of a solar cell is generally considered as the time until its conversion efficiency drops to 90% of the initial value, the life of a light guide can also be considered as the time until the emission intensity of fluorescent substances contained in it drops by 10%. As fluorescent substances are generally intended for use as luminous materials, they are required to have a high fluorescence quantum yield from 100% to 90%. The lifetime of a fluorescent substance therefore can be regarded as the time until its fluorescence quantum yield decreases from the initial value by 10%, that is, until the fluorescence quantum yield drops to 90% to 81%. Thus, fluorescent substances with a fluorescence quantum yield of 80% or lower are usually not used and such a fluorescent substance, if present, is available at a low cost as a low-quality product. Use of such fluorescent substance with low fluorescence quantum yield makes it possible to provide a solar cell module having high generation efficiency at low costs.

While this embodiment uses NPB as an example of the fourth fluorescent substance, this is not a limitation. Other examples of material includes organic fluorescent substances such as N,N′-bis(3-methylphenyl)-N,N′-diphenyl-[1,1′-biphenyl]-4,4′-diamine (TPD), 4,4′-bis-[N-(1-naphthyl)-N-phenylamino]-biphenyl) (a-NPD), 4,4′-bis-[N-(9-phenanthryl)-N-phenylamino]-biphenyl (PPD), N,N,N′,N′-tetra-tolyl-1,1′-cyclohexyl-4,4′-diamine (TPAC), 1,1,4,4-tetraphenyl-1,3-butadiene (TPB), TACP, Poly(N-vinylcarbazole) (PVK), 4,4′,4″-tri(N-carbazolyl)triphenylamine (TCTA), 1,3,5-tris[4-(3-methylphenylphenylamino)phenyl]benzene (m-MTDAPB), 1,3,5-tris[N-(4-diphenylaminophenyl)phenylamino]benzene (p-DPA-TDAB), 4,4,4″-tris(3-methylphenylphenylamino)triphenylamine (m-MTDATA), 4,4′,4″-tris(1-naphthylphenylamino)triphenylamine (1-TNATA), 4,4′,4″-tris(2-naphthylphenylamino)triphenylamine (2-TNATA), 1,3,5-tris(4-tert-butylphenyl-1,3,4-oxadiazolyl)benzene (TPOB), tri(p-terphenyl-4-yl)amine (p-TTA), bis{4-[bis(4-methylphenyl)amino]phenyl}oligothiophene (BMA-nT), 2,5-bis{4-[bis(4-methylphenyl)amino]phenyl}thiophene (BMA-1T), 5,5″-bis{4-[bis(4-methylphenyl)amino]phenyl}-2,2′-bithiophene (BMA-2T), 5,5″-bis{4-[bis(4-methylphenyl)amino]phenyl}-2,2′:5′,2″-terthiophene (BMA-3T), 5,5′″-bis{4-[bis(4-methylphenyl)amino]phenyl}-2,2′:5′,″:5″,2″-quaterthiophene (BMA-4T), 2-(4-biphenyl)-5-(4-tert-butylphenyl)-1,3,4-oxadiazole (PBD), 2,9-dimethyl-4,7-diphenyl-1,10-phenanthroline (BCP), 4,7-diphenyl-1,10-phenanthroline (Bphen), 2,9-bis(naphthalen-2-yl)-4,7-diphenyl-1,10-phenanthroline (NBphen), 1,3-bis[2-(4-tert-butylphenyl)-1,3,4-oxadiazo-5-yl]benzene (OXD-7), 3-(4-biphenyl)-4-phenyl-5-tert-butylphenyl-1,2,4-triazole (TAZ), 4,4′-bis(4,6-diphenyl-1,3,5-triazin-2-yl)biphenyl (BTB), 2,5-Bis(1-naphthyl)-1,3,4-oxadiazole (BND), 4,4′-bis(carbazol-9-yl)biphenyl (CBP), 2,2′,7,7′-tetrakis(carbazol-9-yl)-9,9-spirobifluorene (Spiro-CBP), 1,3,5-tris(carbazol-9-yl)benzene (TCP), 1,3-bis(carbazol-9-yl)benzene (MCP), 4,4′-di(triphenylsilyl)-biphenyl (BSB), 1,4-bis(triphenylsilyl)benzene (UGH-2), 1,3-bis(triphenylsilyl)benzene (UGH-3), and inorganic fluorescent substances formed from quantum dots made of ZnO, CdSe, ZnSe, AlN, GaN, InN, InP, GaP, GaAs, ZnS, CdS, although these are non-limiting examples.

While the host molecule is formed from only one kind of optical functional material (the fourth fluorescent substance) in this embodiment, two or more kinds of optical functional material may be used for the host material. In this case, as the final power production depends on the fluorescence quantum yield of the optical functional material having the longest peak wavelength of the emission spectrum, it is desirable that the fluorescence quantum yield of the optical functional material having the longest peak wavelength of the emission spectrum be higher than that of the other optical functional materials contained in the light guide.

### Fourth Embodiment

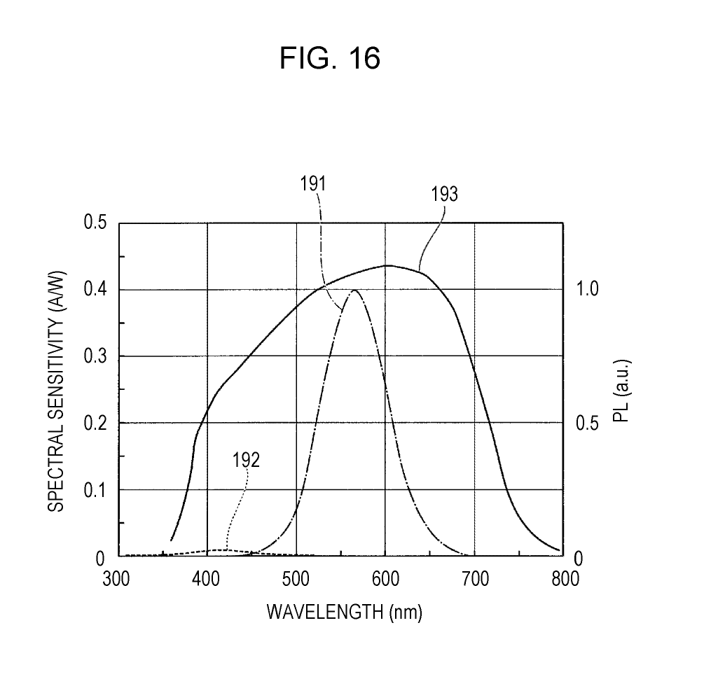

FIG. 16 shows the emission spectrum of optical functional materials and the spectral sensitivity of the solar cell element used in the solar cell module according to a fourth embodiment of the invention. In FIG. 16, reference numeral 191 represents the emission spectrum of a fifth fluorescent substance; reference numeral 192 represents the emission spectrum of a sixth fluorescent substance; and reference numeral 193 represents the spectral sensitivity curve of an amorphous silicon solar cell.

The solar cell module in the third embodiment employs the fourth fluorescent substance having the fluorescence quantum yield of 42% as the host molecule, while the solar cell module according to the fourth embodiment uses a sixth fluorescent substance having a fluorescence quantum yield of 3% as the host molecule. The sixth fluorescent substance has a very low fluorescence quantum yield and can be regarded as a non-luminous material substantially not emitting light. The sixth fluorescent substance serves as the host molecule while the fifth fluorescent substance serves as the guest molecule, so that Foerster energy transfer occurs between the sixth and fifth fluorescent substances to cause substantially only the fifth fluorescent substance, or the guest molecule, to emit light.

The sixth fluorescent substance may be TPDS (N,N,N′,N′-tetra-tolyl-1,1′-diphenylsulphide-4,4′-diamine), for example. The sixth fluorescent substance has a fluorescence quantum yield of 3% and the peak wavelength of its emission spectrum is 420 nm. The fifth fluorescent substance is rubrene as with the third embodiment. The content percentage of the fifth fluorescent substance to the sixth fluorescent substance is 3%. The light guide in this embodiment may be produced by forming a film of an optical functional material layer containing the fourth and fifth fluorescent substances in a thickness of 5 μm on the first principal plane of a transparent light guide made of a 2-mm-thick glass substrate and forming a film of parylene having a thickness of 1 μm on the surface of the optical functional material layer as a transparent protective film, for example.

The solar cell element is an amorphous silicon solar cell. Comparing the spectral sensitivity of the amorphous silicon solar cell at the peak wavelengths of the emission spectrums of the sixth and fifth fluorescent substances, the spectral sensitivity of the amorphous silicon solar cell at the peak wavelength of the emission spectrum of the fifth fluorescent substance, having the longer peak wavelength of the emission spectrum, is greater than the spectral sensitivity of the amorphous silicon solar cell at the peak wavelength of the emission spectrum of the other fluorescent substance (the sixth fluorescent substance) contained in the light guide. Accordingly, use of an amorphous silicon solar cell for the solar cell element enables highly efficient power generation.

The power production measured 5.6 W, the same as the third embodiment, under similar conditions to the first embodiment. Assuming that Foerster energy transfer does not occur and excitation energy from the sixth fluorescent substance transfers to the fifth fluorescent substance through the photoluminescence light emission and absorption process, the power production would be 2.9 W. Thus, the power production is higher by about 93% than the case where the photoluminescence process takes place.

Since a fluorescent substance with low fluorescence quantum yield like the sixth fluorescent substance is inexpensive and has high light resistance, a solar cell module having high generation efficiency can be provided at low costs.

### Fifth Embodiment

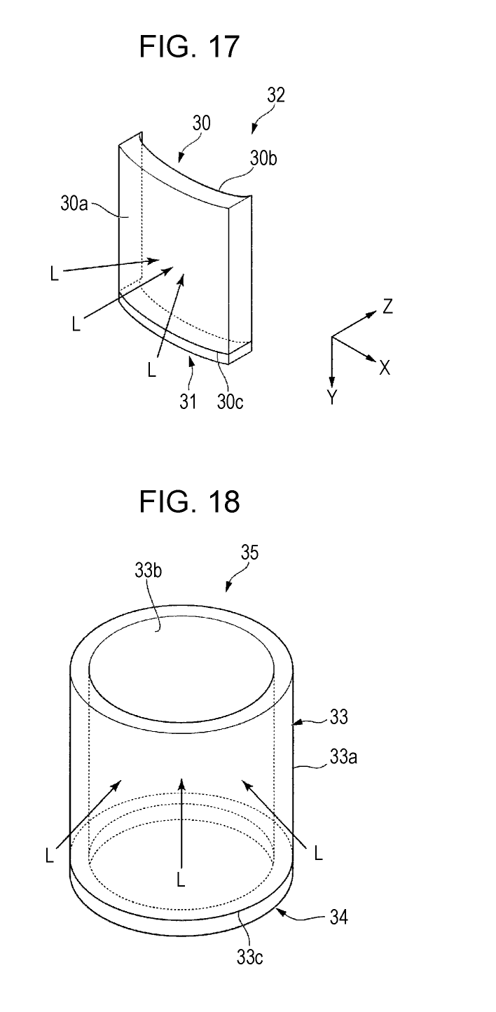

FIG. 17 schematically shows a solar cell module 32 according to a fifth embodiment of the invention. The solar cell module 32 differs from the solar cell module 1 in the first embodiment in the shape and placement of the light guide 30 and the solar cell element 31. Thus, the shape and placement of the light guide 30 and the solar cell element 31 are described below and detailed description of the other components is omitted.

The light guide 30 of the solar cell module 32 is formed as a curved plate-like component, and the solar cell element 31 is designed to receive light having exit from a curved first end face 30c, serving as the light exit surface, of the light guide 30. The light guide 30 has a shape of a plate-like component having a constant thickness being curved about an axis parallel to the Y-axis, for example. Of the first principal plane 30a and the second principal plane 30b of the light guide 30, the first principal plane 30a, having an outwardly convex curve, serves as the light incident surface on which external light (sunlight for example) L is incident.

Light L incident on the light incident surface 30a is absorbed by multiple kinds of optical functional material (not shown) dispersed in the light guide 30. Foerster energy transfer then occurs among the optical functional materials and light emitted by the optical functional material having the longest peak wavelength of the emission spectrum is collected to the light exit surface 30c, which has a smaller area than the light incident surface 30a, to exit therefrom. The multiple kinds of optical functional material dispersed in the light guide 30 may be the first fluorescent substance 8a, the second fluorescent substance 8b, and the third fluorescent substance 8c shown in FIGS. 2 to 6, for example.

The solar cell element 31 is an amorphous silicon solar cell as in the first embodiment. The solar cell element 31 is disposed such that its light receiving surface faces the first end face 30c of the light guide 30. Comparing the spectral sensitivity of the solar cell element 31 at the peak wavelengths of the emission spectrums of the first fluorescent substance 8a, second fluorescent substance 8b, and third fluorescent substance 8c, the spectral sensitivity of the solar cell element 31 at the peak wavelength of the emission spectrum of the optical functional material having the longest peak wavelength of the emission spectrum (third fluorescent substance 8c) among the multiple optical functional materials (the first fluorescent substance 8a, the second fluorescent substance 8b, and the third fluorescent substance 8c) is greater than the spectral sensitivity of the solar cell element 31 at the peak wavelengths of the emission spectrums of the other optical functional materials (the first and second fluorescent substances 8a, 8b) contained in the light guide 30. The solar cell module 32 thereby provides high generation efficiency.

The light incident surface 30a of the light guide 30 of the solar cell module 32 is a curved face. This prevents significant variations in power production even when the incident angle of light L varies in the curving direction of the light guide 30 with time such as in the daytime and the evening. In electrical power generation with a solar cell, the angle of the solar cell is typically controlled in two axial directions with a tracking device so that the light receiving surface of the solar cell is oriented in the light incident direction. With the light incident surface 30a of the light guide 30 designed in a curved shape so as to be oriented in different directions as in this embodiment, in contrast, a tracking device needs not be provided. Even if a tracking device is employed, its configuration can be simplified as compared to the case of angle control in two axial directions because only angle control in the direction orthogonal to the curving direction is required. While the light guide 30 is shaped to be curved in one direction in this embodiment, this is not a limitation. For example, it may be dome-shaped like a hemisphere or a bell, in which case the tracking device is not necessary.

The curved shape of the light guide 30 in the solar cell module 32 allows the light guide 30 to be installed on a building wall or roof having a curved contour. While the light guide 30 in this embodiment is shaped to be curved in one direction, it is not limited to such a simple form. It may be designed to have any appropriate shape such as a roof tile or wavy shape, for example.

The light guide 30 may have a bent shape having a ridge, instead of a curved shape, as appropriate for where it is installed. A curved or bent plane has to be provided in at least part of the light incident surface, with which the aforementioned effects are achieved.

### Sixth Embodiment

FIG. 18 schematically illustrates a solar cell module 35 according to a sixth embodiment of the invention. The solar cell module 35 differs from the solar cell module 1 in the first embodiment in the shape and placement of the light guide 33 and the solar cell element 34. Thus, the shape and placement of the light guide 33 and the solar cell element 34 are described below and detailed description of the other components is omitted.

The light guide 33 of the solar cell module 35 is formed as a tubular component with its center axis parallel to the Y-axis, and the solar cell element 34 is designed to receive light having exit from the first end face 33c, serving as the light exit surface, of the light guide 33. The light guide 33 has a cylindrical shape having a constant thickness, for example. The outer circumferential surface of the light guide 33 is the first principal plane 33a and the inner circumferential surface of the light guide 33 is the second principal plane 33b. Of the first principal plane 33a and the second principal plane 33b of the light guide 33, the first principal plane 33a, having an outwardly convex curve, serves as the light incident surface on which external light (sunlight for example) L is incident.

Light L incident on the light incident surface 33a is absorbed by multiple kinds of optical functional material (not shown) dispersed in the light guide 33. Then, Foerster energy transfer occurs among the optical functional materials, and light emitted by the optical functional material having the longest peak wavelength of the emission spectrum is collected to the light exit surface 33c, which has a smaller area than the light incident surface 33a, to exit therefrom. The multiple kinds of optical functional material dispersed in the light guide 33 may be the first fluorescent substance 8a, the second fluorescent substance 8b, and the third fluorescent substance 8c shown in FIGS. 2 to 6, for example.

The solar cell element 34 is an amorphous silicon solar cell as in the first embodiment. The solar cell element 34 is disposed such that its light receiving surface faces the first end face 33c of the light guide 33. Comparing the spectral sensitivity of the solar cell element 34 at the peak wavelengths of the emission spectrums of the first fluorescent substance 8a, second fluorescent substance 8b, and third fluorescent substance 8c, the spectral sensitivity of the solar cell element 34 at the peak wavelength of the emission spectrum of the optical functional material having the longest peak wavelength of the emission spectrum (third fluorescent substance 8c) among the multiple optical functional materials (the first fluorescent substance 8a, the second fluorescent substance 8b, and the third fluorescent substance 8c) is greater than the spectral sensitivity of the solar cell element 34 at the peak wavelengths of the emission spectrums of the other optical functional materials (the first and second fluorescent substances 8a, 8b) contained in the light guide 33. The solar cell module 35 thereby provides high generation efficiency.

The light incident surface 33a of the light guide 33 of the solar cell module 35 is a curved plane. This prevents significant variations in power production even when the incident angle of light L varies in the curving direction of the light guide 33 with time such as in the daytime and the evening. Also, the tubular shape of the light guide 33 enables the light guide 33 to be installed on a post of a building, a power pole, or the like. While the light guide 33 has a cylindrical shape in this embodiment, this is not a limitation; the light guide 33 may be formed in any shape appropriate for where it is installed, such as a shape having an elliptical or polygonal cross section on a plane parallel to the X-Z plane.

### Seventh Embodiment

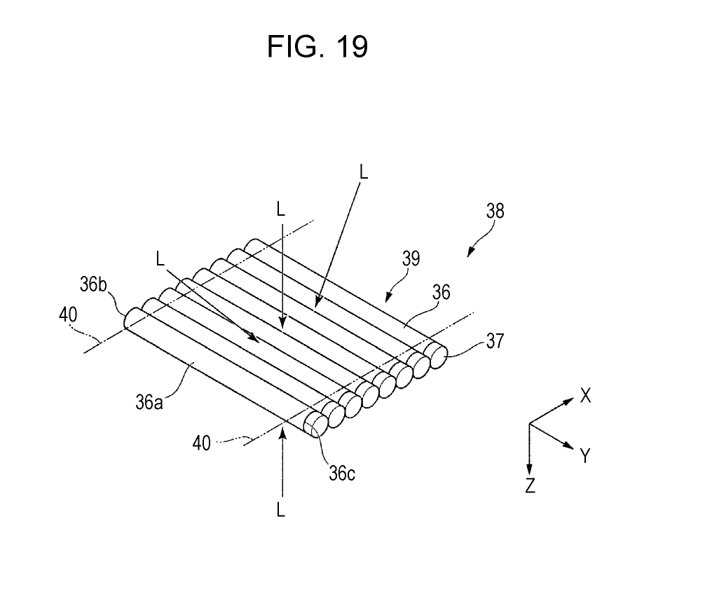

FIG. 19 schematically illustrates a solar cell module 38 according to a seventh embodiment of the invention. The solar cell module 38 differs from the solar cell module 1 in the first embodiment in the shape and placement of the light guide 36 and the solar cell element 37. Thus, the shape and placement of the light guide 36 and the solar cell element 37 are described below and detailed description of the other components is omitted.

The light guide 36 of the solar cell module 38 is formed as a column-shaped component extending in the Y-direction, and the solar cell element 37 is designed to receive light having exit from the first end face 36c, serving as the light exit surface, of the light guide 36. The light guide 36 has a circular cylindrical shape with the central axis parallel to the Y-axis, for example. The outer circumferential surface of the light guide 36 is the first principal plane 36a, which serves as the light incident surface on which external light (sunlight for example) L is incident.

The solar cell element 37 is an amorphous silicon solar cell as in the first embodiment. The solar cell element 37 is disposed such that its light receiving surface faces the first end face 36c of the light guide 36. Comparing the spectral sensitivity of the solar cell element 37 at the peak wavelengths of the emission spectrums of the first fluorescent substance 8a, second fluorescent substance 8b, and third fluorescent substance 8c, the spectral sensitivity of the solar cell element 37 at the peak wavelength of the emission spectrum of the optical functional material having the longest peak wavelength of the emission spectrum (third fluorescent substance 8c) among the multiple optical functional materials (the first fluorescent substance 8a, the second fluorescent substance 8b, and the third fluorescent substance 8c) is greater than the spectral sensitivity of the solar cell element 37 at the peak wavelengths of the emission spectrums of the other optical functional materials (the first and second fluorescent substances 8a, 8b) contained in the light guide 36. The solar cell module 38 thereby provides high generation efficiency.

While FIG. 19 shows that eight module units 39 each of which is a pair of a light guide 36 and a solar cell element 37 are disposed side by side in the X-direction, the number of module units 39 is not limited to eight.

There may be one or any number other than eight of module units 39. If multiple module units 39 are provided, they can be installed on a flat surface. Flexible connection of multiple module units 39 with a string-like connection member 40 enables installation on a non-flat surface with their shape freely varied and also enables such a way of handling as unrolling them when necessary and rolling them for storage when not necessary like a bamboo blind. In a case where multiple module units 39 are connected such that they are spaced from each other with a solid rod-like connection member 40, wind passes through the spaces between light guide 36, so wind pressure can be mitigated and the solar cell module can be easily installed on a mount.

While the light guide 36 has a circular cylindrical shape in this embodiment, this is not a limitation; the light guide 36 may be formed in any shape appropriate for where it is installed, such as a shape having an elliptical or polygonal cross section on a plane parallel to the X-Z plane.

The light incident surface 36a of the light guide 36 of the solar cell module 38 is a curved plane. This prevents significant variations in power production even when the incident angle of light L varies in the curving direction of the light guide 36 with time such as in the daytime and the evening. Additionally, due to the columnar shape of the light guide 36, by flexibly connecting multiple light guides 36 in alignment, they can be installed on a curved surface in addition to a flat surface and also can be unrolled and rolled like a bamboo blind.

### [Photovoltaic Power Generation Device]

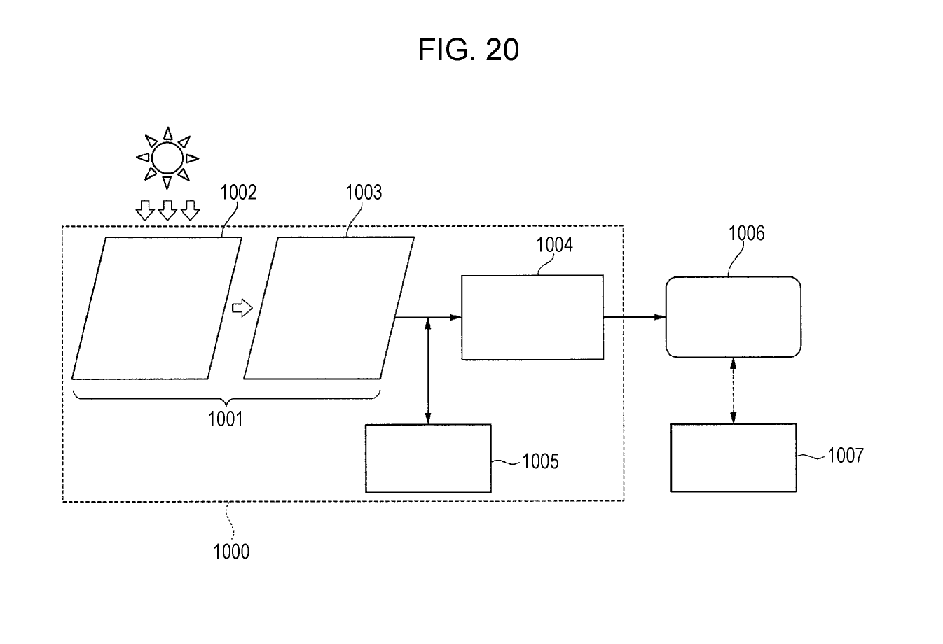

FIG. 20 shows a schematic configuration of a photovoltaic power generation device 1000.

The photovoltaic power generation device 1000 includes a solar cell module 1001, an inverter (DC/AC converter) 1004, and a storage battery 1005. The solar cell module 1001 converts sunlight energy into electrical power. The inverter (DC/AC converter) 1004 converts direct current power output from the solar cell module 1001 to alternate current power. The storage battery 1005 stores the direct current power output from the solar cell module 1001.

The solar cell module 1001 includes a light guide 1002 for collecting sunlight and a solar cell element 1003 that produces power with sunlight collected by the light guide 1002.

The solar cell module 1001 may be any of the solar cell modules described in the first to ninth embodiments, for example.

The photovoltaic power generation device 1000 supplies power to an external electronic device 1006. The electronic device 1006 is supplied with power by an auxiliary power source 1007 as necessary.

Since the photovoltaic power generation device 1000 includes the inventive solar cell module described earlier, it provides high generation efficiency.

### INDUSTRIAL APPLICABILITY

The aspects of the invention are applicable to solar cell modules and photovoltaic power generation devices.

### REFERENCE SIGNS LIST

1 solar cell module
4 light guide
4a light incident surface
4c light exit surface
6 solar cell element
7 reflective layer
8a, 8b, 8c fluorescent substance (optical functional material)
9 reflective layer
24 light guide
25 transparent light guide
25a first principal plane
26 fluorescent film (optical functional material layer)
28 adhesive layer
30 light guide
30 light incident surface
30c light exit surface
31 solar cell element
32 solar cell module
33 light guide
33a light incident surface
33c light exit surface
34 solar cell element
35 solar cell module
36 light guide
36a light incident surface
36c light exit surface
37 solar cell element
38 solar cell module
39 module unit
40 connection member
1000 photovoltaic power generation device
L, L1 light

1-19. (canceled)

20. A solar cell module comprising:
a light guide that has a light incident surface and a light exit surface having an area smaller than the light incident surface and that contains a plurality of optical functional materials, wherein part of external light incident on the light incident surface is absorbed by the plurality of optical functional materials, Foerster energy transfer occurs among the plurality of optical functional materials, and light emitted by the optical functional material having a longest peak wavelength of an emission spectrum among the plurality of optical functional materials is collected to and exits from the light exit surface; and
a solar cell element that receives the light exiting from the light exit surface;
wherein a spectral sensitivity of the solar cell element at the peak wavelength of the emission spectrum of the optical functional material having the longest peak wavelength of the emission spectrum among the plurality of optical functional materials is higher than the spectral sensitivity of the solar cell element at peak wavelengths of the emission spectrum of any of other optical functional materials contained in the light guide,
among the plurality of optical functional materials, one or more optical functional materials other than the optical functional material having the longest peak wavelength of the emission spectrum include an optical functional material having fluorescence quantum yield of 80% or less.

21. The solar cell module according to claim 20, wherein the fluorescence quantum yield of the optical functional material having the longest peak wavelength of the emission spectrum is higher than the fluorescence quantum yield of the other optical functional materials contained in the light guide.

22. The solar cell module according to claim 20, wherein the light guide contains optical functional materials formed from inorganic materials as the plurality of optical functional materials.

23. The solar cell module according to claim 22, wherein the light guide contains optical functional materials formed from quantum dots as the optical functional materials formed from inorganic materials.

24. The solar cell module according to claim 20, further comprising:
a reflective layer that reflects light propagating from inside the light guide to outside the light guide so as to direct the light toward the inside of the light guide;
wherein the reflective layer is provided with an air layer interposed between the reflective layer and the light guide or in direct contact with the light guide without an air layer.

25. The solar cell module according to claim 24, wherein the reflective layer is a scattering reflective layer that reflects and scatters incident light.

26. The solar cell module according to claim 20, wherein the light guide includes a transparent light guide and the plurality of optical functional materials dispersed in the transparent light guide.

27. The solar cell module according to claim 20, wherein the light guide includes a transparent light guide and an optical functional material layer which is disposed on a first principal plane of the transparent light guide and in which the plurality of optical functional materials are dispersed.

28. The solar cell module according to claim 27, further comprising:
a removable adhesive layer;
wherein the transparent light guide and the optical functional material layer are bonded together by the adhesive layer.

29. The solar cell module according to claim 20, wherein the light incident surface is a flat plane.

30. The solar cell module according to claim 29,
wherein the light guide is a flat plate-like component, and
wherein the solar cell element receives light exiting from an end face of the light guide that serves as the light exit surface.

31. The solar cell module according to claim 20, wherein at least part of the light incident surface is a bent or curved plane.

32. The solar cell module according to claim 31,
wherein the light guide is formed as a curved plate-like component, and
wherein the solar cell element receives light exiting from a curved end face of the light guide that serves as the light exit surface.

33. The solar cell module according to claim 31,
wherein the light guide is formed as a tubular component, and
wherein the solar cell element receives light exiting from an end face of the light guide that serves as the light exit surface.

34. The solar cell module according to claim 31,
wherein the light guide is formed as a column-shaped component, and
wherein the solar cell element receives light exiting from an end face of the light guide that serves as the light exit surface.

35. The solar cell module according to claim 34, further comprising:
a string-like connection member;
wherein a plurality of module units each of which is a pair of the light guide and the solar cell element are arranged alongside each other, and
wherein the plurality of module units are flexibly connected with each other by the string-like connection member.

36. The solar cell module according to claim 34, wherein a plurality of module units each of which is a pair of the light guide and the solar cell element are arranged alongside each other, and the plurality of module units are connected such that they are spaced from each other.

37. A photovoltaic power generation device comprising:
the solar cell module according to claim 20.
